(19) United States
(12) Patent Application Publication
(10) Pub. No.: US 2026/0213763 A1
(43) Pub. Date: Jul. 23, 2026

(54) SIGNAL SAMPLING DEVICE AND SIGNAL SAMPLING METHOD

(71) Applicant: REALTEK SEMICONDUCTOR CORPORATION, HSINCHU (TW)

(72) Inventor: SHIH-HSIUNG HUANG, HSINCHU (TW)

(21) Appl. No.: 19/446,191

(22) Filed: Jan. 12, 2026

(30) Foreign Application Priority Data
Jan. 23, 2025 (TW) 114103203

(51) Int. Cl. H03M 1/12; H03M 1/50

(52) U.S. Cl. CPC H03M 1/1245; H03M 1/50

(57) ABSTRACT

A signal sampling device includes a first buffer circuit, a second buffer circuit, and a first bootstrap switch circuit. The first buffer circuit is configured to generate a first buffer signal according to an input signal. A second buffer circuit is configured to generate a second buffer signal according to the input signal, in which a specification requirement of the second buffer circuit is lower than that of the first buffer circuit. The first bootstrap switch circuit is configured to generate a control voltage according to the second buffer signal and to sample the first buffer signal according to the control voltage to generate a first sampling signal.

### BACKGROUND OF THE INVENTION

### 1. Field of the Invention

The present disclosure relates to a signal sampling device, and more particularly to a signal sampling device and a signal sampling method that are capable of reducing noise influence and reducing circuit cost.

### 2. Description of Related Art

An analog-to-digital converter needs to employ a sampling circuit to sample an analog signal to be quantized. Therefore, performance of the sampling circuit directly affects signal quality of the analog-to-digital converter. In order to improve performance of the sampling circuit, some related approaches utilize a switch having better performance to implement the sampling circuit. However, an auxiliary circuit of the switch may generate kickback noise during signal sampling. To reduce influence of the kickback noise, these related approaches utilize a buffer circuit with higher specification requirements or several series-connected buffer circuits, resulting in significant increase of circuit area and cost. In addition, if the several series-connected buffer circuits are employed, performance of the switch may also be reduced.

### SUMMARY OF THE INVENTION

In some embodiments, an object of the present disclosure is, but not limited to, providing a signal sampling device and a signal sampling method capable of reducing noise influence and reducing circuit cost, so as to improve deficiencies of the prior art.

In some embodiments, a signal sampling device includes a first buffer circuit, a second buffer circuit and a first bootstrap switch circuit. The first buffer circuit is configured to generate a first buffer signal according to an input signal. The second buffer circuit is configured to generate a second buffer signal according to the input signal, wherein a specification requirement of the second buffer circuit is lower than a specification requirement of the first buffer circuit. The first bootstrap switch circuit is configured to generate a control voltage according to the second buffer signal, and sample the first buffer signal according to the control voltage to generate a first sampling signal.

In some embodiments, a signal sampling method includes the following operations: generating, by a first buffer circuit, a first buffer signal according to an input signal; generating, by a second buffer circuit, a second buffer signal according to the input signal, wherein a specification requirement of the second buffer circuit is lower than a specification requirement of the first buffer circuit; and generating, by a first bootstrap switch circuit, a control voltage according to the second buffer signal, and sampling the first buffer signal according to the control voltage to generate a first sampling signal.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a signal sampling device according to some embodiments of the present disclosure.

FIG. 2 illustrates a schematic diagram of a signal sampling device according to some embodiments of the present disclosure.

FIG. 3 illustrates a schematic diagram of a buffer circuit in FIG. 1 or FIG. 2 according to some embodiments of the present disclosure.

FIG. 4A illustrates a schematic diagram of a buffer circuit in FIG. 1 or FIG. 2 according to some embodiments of the present disclosure.

FIG. 4B illustrates a schematic diagram of a buffer according to some embodiments of the present disclosure.

FIG. 5 illustrates a flowchart of a signal sampling method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may indicate a system formed with at least one circuit, and the term “circuit” may indicate an object, which is formed with one or more transistors and/or one or more active/passive elements based on a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, elements in various figures are designated with the same reference number.

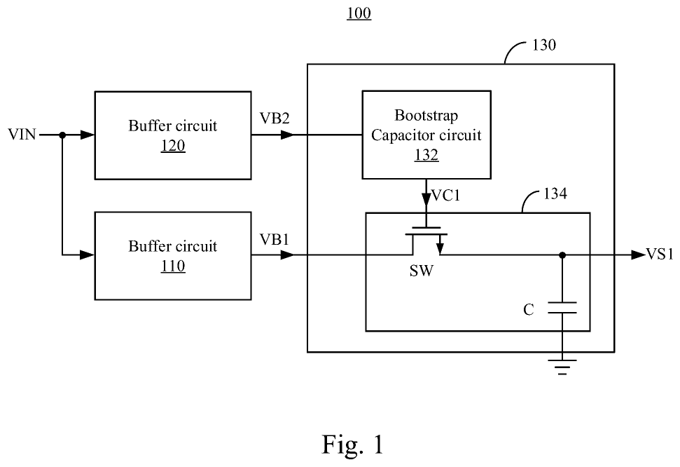

FIG. 1 illustrates a schematic diagram of a signal sampling device 100 according to some embodiments of the present disclosure. In some embodiments, a signal sampling device 100 may include a buffer circuit 110, a buffer circuit 120 and a bootstrap switch circuit 130. The buffer circuit 110 is configured to generate a buffer signal VB1 according to an input signal VIN. The buffer circuit 120 is configured to generate a buffer signal VB2 according to the input signal VIN. In some embodiments, the level of buffer signal VB2 is substantially the same as the level of the buffer signal VB1. The bootstrap switch circuit 130 is configured to generate a control voltage VC1 according to the buffer signal VB2, and sample the buffer signal VB1 according to the control voltage VC1 to generate a sampling signal VS1.

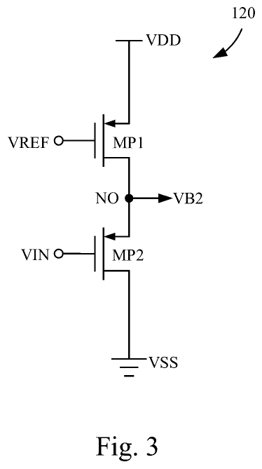

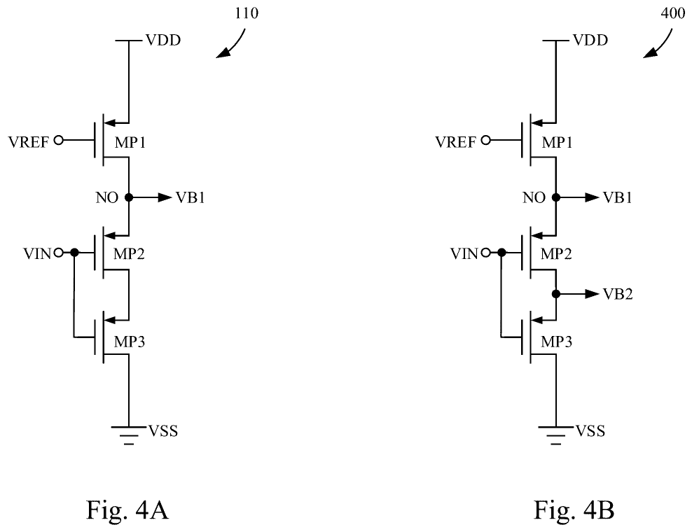

In greater detail, the bootstrap switch circuit 130 may include a bootstrap capacitor circuit 132 and a sampling circuit 134. The bootstrap capacitor circuit 132 may include switches (not shown) and at least one capacitor (not shown), in which the switches may be switched according to one or more clock signals (not shown), in order to utilize the buffer signal VB2 to charge and/or discharge the at least one capacitor, thereby generating the control voltage VC1 through the at least one capacitor, that is, generating the control voltage VC1 according to the buffer signal VB2. In some embodiments, during a period when the bootstrap switch circuit 130 samples the buffer signal VB1, the bootstrap switch circuit 130 may maintain a voltage difference between the control voltage VC1 and the buffer signal VB1. In other words, during the period, a fixed voltage difference (the difference may be, but is not limited to, a supply voltage VDD shown in FIG. 3, FIG. 4A or FIG. 4B) is between the control voltage VC1 and the buffer signal VB1. As a result, a switch SW controlled by the control voltage VC1 in the sampling circuit 134 may have a more stable (or fixed) on-resistance during the period of sampling the buffer signal VB1, in order to improve overall linearity and precision, thereby improving the sampling accuracy. The sampling circuit 134 is turned on according to the control voltage VC1 to sample the buffer signal VB1 and accordingly generate a sampling signal VS1. For example, the sampling circuit 134 may include a switch SW and a capacitor C. The switch SW may be controlled by the control voltage VC1, and the capacitor C may store the buffer signal VB1 when the switch SW is turned on and accordingly generate the sampling signal VS1. Detailed circuit arrangements of the bootstrap switch circuit 130 are understood by a person having ordinary skill in the art and thus will not be described herein.

In some embodiments, specification requirement(s) of the buffer circuit 120 may be lower than specification requirement(s) of the buffer circuit 110. For example, the above specification requirements may include, but are not limited to, bandwidth, linearity, area, current consumption, rated voltage and the like. For example, the bandwidth of the buffer circuit 120 is lower than the bandwidth of the buffer circuit 110. The linearity of the buffer circuit 120 is lower than the linearity of the buffer circuit 110. The area of the buffer circuit 120 is smaller than the area of the buffer circuit 110. The current consumption of the buffer circuit 120 is lower than the current consumption of the buffer circuit 110. A rated voltage of the buffer circuit 120 is lower than a rated voltage of the buffer circuit 110. Based on FIG. 1, the buffer signal VB2 generated by the buffer circuit 120 is mainly provided to the bootstrap switch circuit 130 to generate the control voltage VC1, and the buffer signal VB1 generated by the buffer circuit 110 is utilized to generate the sampling signal VS1. In other words, a signal path for generating the sampling signal VS1 based on the buffer signal VB1 is a main path of the signal sampling device 100 for generating the sampling signal VS1, and a signal path for generating the control voltage VC1 based on the buffer signal VB2 is a relatively secondary path. As the main path is utilized to generate the sampling signal VS1 having high resolution, if the main path is affected by kickback noise, quality of the sampling signal VS1 is significantly reduced and difficult to recover. Therefore, by providing another secondary path, the buffer circuit 110 having higher specification may be arranged for the above-mentioned main path and the buffer circuit 120 having lower specification may be arranged for the above-mentioned secondary path. As a result, while improving performance of the main path (for example, improving resolution and linearity of the sampling signal VS1), overall circuit area and cost can be reduced at the same time. By providing the buffer circuit 120, influence of kickback noise generated by the bootstrap switch circuit 130 can be further reduced, thereby improving overall performance.

In some related approaches, a signal sampling device may employ multiple series-connected buffer circuits, in which a first buffer circuit generates a first signal according to an input signal, and a second buffer circuit generates a second signal according to the first signal, and a bootstrap switch circuit in the signal sampling device generates a control voltage according to the second signal and samples the first signal according to the control voltage. In the above approaches, as the buffer circuits are connected in series, there will be a certain phase error between the first signal and the second signal, such that a fixed voltage difference between the control voltage and the first signal cannot be accurately maintained, resulting in degradation of performance of the signal sampling device in the approaches. In addition, since the several buffer circuits are connected in series, kickback noise generated by the bootstrap switch circuit may affect the first buffer circuit through the second buffer circuit, thereby degrading overall performance. Furthermore, because the buffer circuits are connected in series, the first buffer circuit, in addition to driving a sampling circuit, also needs to drive the second buffer circuit, and a specification requirement (for example, current driving capability) of the first buffer circuit will increase accordingly, causing overall circuit cost to increase significantly.

Compared with the above approaches, in some embodiments of the present disclosure, by providing the buffer circuits 110 and the buffer circuits 120 arranged in parallel, circuit specification requirements can be reduced, and phase errors can be avoided at the same time, so that the above fixed voltage difference can be maintained more accurately. As a result, overall circuit performance can be maintained while circuit cost is reduced.

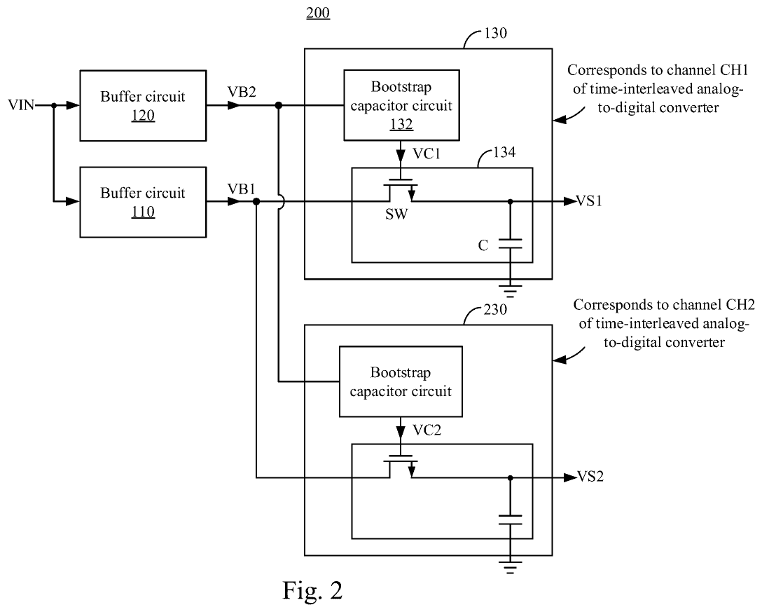

FIG. 2 illustrates a schematic diagram of a signal sampling device 200 according to some embodiments of the present disclosure. Compared with FIG. 1, the signal sampling device 200 further includes a bootstrap switch circuit 230. The bootstrap switch circuit 230 may generate a control voltage VC2 according to the buffer signal VB2, and sample the buffer signal VB1 according to the control voltage VC2 to generate a sampling signal VS2. In this example, the signal sampling device 200 may be applied to a time-interleaved analog-to-digital converter. For example, the bootstrap switch circuit 130 may correspond to a channel CH1 of the time-interleaved analog-to-digital converter, and the bootstrap switch circuit 230 may correspond to a channel CH2 of the time-interleaved analog-to-digital converter. In other words, the bootstrap switch circuit 130 and the bootstrap switch circuit 230 may sample the buffer signal VB1 in sequence, in order to generate the sampling signal VS1 and the sampling signal VS2 in sequence. Similarly, by providing the buffer circuits 110 and the buffer circuits 120 arranged in parallel, kickback noise or signal disturbance from different channels can be prevented from affecting the buffer circuit 110 that processes the main path, thereby improving signal quality of the sampling signal VS1 and the sampling signal VS2.

Circuit arrangements in FIG. 1 and FIG. 2 are shown with examples of single-ended signal applications, but the present disclosure is not limited thereto. In other embodiments, the signal sampling device 100 and/or the signal sampling device 200 may be provided with more buffer circuits and corresponding bootstrap switch circuits to be applied to differential signal applications. Therefore, the present disclosure is not limited to circuit arrangements and numbers of circuits shown in FIG. 1 and FIG. 2.

FIG. 3 illustrates a schematic diagram of the buffer circuit 120 in FIG. 1 or FIG. 2 according to some embodiments of the present disclosure. In some embodiments, the buffer circuit 120 may be an analog buffer circuit, for example, a source follower circuit. For example, the buffer circuit 120 includes a transistor MP1 and a transistor MP2. A first terminal (e.g., a source) of the transistor MP1 receives a supply voltage VDD, a second terminal (e.g., a drain) of the transistor MP1 is coupled to an output node NO, and a control terminal (e.g., a gate) of the transistor MP1 receives a reference voltage VREF. A first terminal of the transistor MP2 and the second terminal of the transistor MP1 are coupled to an output node NO and output the buffer signal VB2, a second terminal of the transistor MP2 receives a supply voltage VSS, and a control terminal of the transistor MP2 receives the input signal VIN. With the above arrangement, the transistor MP1 may operate as a current source according to the reference voltage VREF and the supply voltage VDD to drive the transistor MP2, and the transistor MP2 may generate the buffer signal VB2 according to the input signal VIN.

FIG. 4A illustrates a schematic diagram of the buffer circuit 110 in FIG. 1 or FIG. 2 according to some embodiments of the present disclosure. In some embodiments, the buffer circuit 110 may also be an analog buffer circuit, for example, a source follower circuit. Compared with the buffer circuit 120 of FIG. 3, the buffer circuit 110 further includes a transistor MP3. The transistor MP1 operates as a current source according to the reference voltage VREF and the supply voltage VDD. The transistor MP2 and the transistor MP3 are coupled in series, and the transistor MP2 and the transistor MP1 are coupled to the output node NO. In greater detail, in this example, a first terminal of the transistor MP2 is configured to output the buffer signal VB1, and a second terminal of the transistor MP2 is coupled to a first terminal of the transistor MP3. A second terminal of the transistor MP3 receives the supply voltage VSS, and a control terminal of the transistor MP3 receives the input signal VIN. Thus, the transistor MP2 and the transistor MP3 may generate the buffer signal VB1 according to the input signal VIN. Compared with the arrangement of FIG. 3, by arranging the transistor MP3, linearity of the buffer circuit 110 can be further improved.

FIG. 4B illustrates a schematic diagram of a buffer 400 according to some embodiments of the present disclosure. In some embodiments, if a current application has a lower requirement for noise performance, the buffer circuit 110 and the buffer circuit 120 in FIG. 1 or FIG. 2 may be integrated into a single buffer. For example, the above buffer circuit 110 and buffer circuit 120 may be implemented as the buffer 400 of FIG. 4B to jointly generate the buffer signal VB1 and the buffer signal VB2, in which the transistor MP2 is coupled between the transistor MP1 and the transistor MP3, and the transistor MP3 is configured to generate the buffer signal VB2 according to the input signal VIN. Circuit arrangement in FIG. 4B is generally the same as FIG. 4A and will not be described repeatedly.

In FIG. 4A or FIG. 4B, respective potential levels of the first terminal, the second terminal and the control terminal of the transistor MP2 vary with the input signal VIN, so voltage differences between the above terminals are relatively fixed, enabling the transistor MP2 to have relatively good linearity, thereby generating the buffer signal VB1 having higher linearity. Conversely, as the second terminal of the transistor MP3 receives the supply voltage VSS, the second terminal of the transistor MP3 has a fixed potential level, resulting in a relatively unstable voltage difference between the multiple terminals of the transistor MP3. Under this condition, the transistor MP3 has relatively lower linearity, thereby making the buffer signal VB2 have lower linearity (compared to the buffer signal VB1). On the other hand, although the transistor MP1, the transistor MP2, and the transistor MP3 are arranged in the same path, as the transistor MP2 is coupled between the transistor MP1 and the transistor MP3 (that is, arranged between a node that outputs the buffer signal VB1 (e.g., the output node NO) and a node that outputs the buffer signal VB2 (e.g., the second terminal of the transistor MP2)), the transistor MP2 may provide a certain buffering effect for the buffer signal VB1 and the buffer signal VB2 to reduce influence of kickback noise.

In other embodiments, the output node NO may be configured to output the buffer signal VB2, and a second terminal of the transistor MP2 may be configured to output the buffer signal VB1. Various circuit arrangements that are able to generate the corresponding buffer signal VB1 and buffer signal VB2 are within the contemplated scope of the present disclosure. In the examples of FIG. 3, FIG. 4A and FIG. 4B, each of the transistors MP1, MP2 and MP3 may be a P-type transistor. In other examples, the circuit arrangements of FIG. 3, FIG. 4A and FIG. 4B may be implemented with transistors having other conductivity types. Therefore, the above arrangements regarding the buffer circuit 110, the buffer circuit 120 and/or the buffer 400 are given for illustrative purposes, and the present disclosure is not limited thereto.

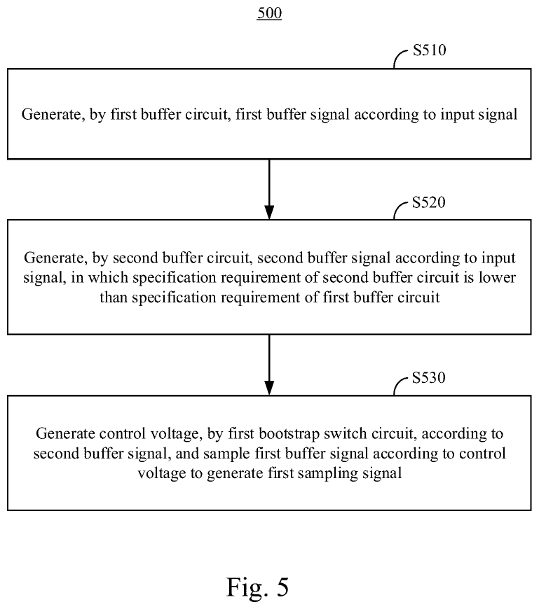

FIG. 5 illustrates a flowchart of a signal sampling method 500 according to some embodiments of the present disclosure. In operation S510, a first buffer signal is generated by a first buffer circuit according to an input signal. In operation S520, a second buffer signal is generated by a second buffer circuit according to the input signal, in which a specification requirement of the second buffer circuit is lower than a specification requirement of the first buffer circuit. In operation S530, a control voltage is generated by a first bootstrap switch circuit according to the second buffer signal, and the first buffer signal is sampled according to the control voltage to generate a first sampling signal.

Operations related to the signal sampling method 500 may be understood with reference to descriptions of the above embodiments and will not be repeated herein. Operations in the signal sampling method 500 are merely examples and are not necessarily performed in the order shown in this example. Without departing from operation modes and scope of various embodiments of the present disclosure, related operations in the signal sampling method 500 may be appropriately added, replaced, omitted, or performed in a different order. Alternatively, related operations in the above operations may be performed simultaneously or partially simultaneously.

As described above, a signal sampling device and a signal sampling method provided in some embodiments of the present disclosure may utilize parallel buffer circuits to reduce overall circuit cost and improve quality of a sampling signal at the same time.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications based on the claims of the present disclosure are all consequently viewed as being embraced by the scope of the present disclosure.

What is claimed is:

1. A signal sampling device, comprising:
a first buffer circuit configured to generate a first buffer signal according to an input signal;
a second buffer circuit configured to generate a second buffer signal according to the input signal, wherein a specification requirement of the second buffer circuit is lower than a specification requirement of the first buffer circuit; and
a first bootstrap switch circuit configured to generate a control voltage according to the second buffer signal, and sample the first buffer signal according to the control voltage to generate a first sampling signal.

2. The signal sampling device of claim 1, further comprising:
a second bootstrap switch circuit configured to generate a second control voltage according to the second buffer signal, and sample the first buffer signal according to the second control voltage to generate a second sampling signal.

3. The signal sampling device of claim 2, wherein the first bootstrap switch circuit corresponds to a first channel of a time-interleaved analog-to-digital converter, and the second bootstrap switch circuit corresponds to a second channel of the time-interleaved analog-to-digital converter.

4. The signal sampling device of claim 1, wherein the first buffer circuit and the second buffer circuit are integrated into a buffer, and the buffer comprises:
a first transistor configured to operate as a current source according to a reference voltage and a supply voltage; and
a second transistor configured to generate the second buffer signal according to the input signal; and
a third transistor coupled between the first transistor and the second transistor and configured to generate the first buffer signal according to the input signal.

5. The signal sampling device of claim 1, wherein a bandwidth of the second buffer circuit is lower than a bandwidth of the first buffer circuit.

6. The signal sampling device of claim 1, wherein linearity of the second buffer circuit is lower than linearity of the first buffer circuit.

7. The signal sampling device of claim 1, wherein an area of the second buffer circuit is smaller than an area of the first buffer circuit.

8. The signal sampling device of claim 1, wherein the second buffer circuit comprises:
a first transistor configured to operate as a current source according to a reference voltage and a supply voltage; and
a second transistor, wherein the second transistor and the first transistor are coupled to an output node and the second transistor is configured to generate the second buffer signal according to the input signal.

9. The signal sampling device of claim 1, wherein the first buffer circuit comprises:
a first transistor configured to operate as a current source according to a reference voltage and a supply voltage; and
a plurality of second transistors coupled in series, wherein the plurality of second transistors and the first transistor are coupled to an output node, and the plurality of second transistors are configured to generate the first buffer signal according to the input signal.

10. The signal sampling device of claim 1, wherein the first bootstrap switch circuit comprises:
a bootstrap capacitor circuit configured to generate the control voltage according to the second buffer signal, wherein, during a period when the first bootstrap switch circuit samples the first buffer signal, a fixed voltage difference is between the control voltage and the first buffer signal; and
a sampling circuit configured to be turned on according to the control voltage to sample the first buffer signal and generate the first sampling signal.

11. The signal sampling device of claim 1, wherein current consumption of the second buffer circuit is lower than current consumption of the first buffer circuit.

12. The signal sampling device of claim 1, wherein a rated voltage of the second buffer circuit is lower than a rated voltage of the first buffer circuit.

13. A signal sampling method, comprising:
generating, by a first buffer circuit, a first buffer signal according to an input signal;
generating, by a second buffer circuit, a second buffer signal according to the input signal, wherein a specification requirement of the second buffer circuit is lower than a specification requirement of the first buffer circuit; and
generating, by a first bootstrap switch circuit, a control voltage according to the second buffer signal, and sampling the first buffer signal according to the control voltage to generate a first sampling signal.

14. The signal sampling method of claim 13, further comprising:
generating, by a second bootstrap switch circuit, a second control voltage according to the second buffer signal, and sampling the first buffer signal according to the second control voltage to generate a second sampling signal.

15. The signal sampling method of claim 14, wherein the first bootstrap switch circuit corresponds to a first channel of a time-interleaved analog-to-digital converter, and the second bootstrap switch circuit corresponds to a second channel of the time-interleaved analog-to-digital converter.

16. The signal sampling method of claim 13, wherein a bandwidth of the second buffer circuit is lower than a bandwidth of the first buffer circuit.

17. The signal sampling method of claim 13, wherein linearity of the second buffer circuit is lower than linearity of the first buffer circuit.

18. The signal sampling method of claim 13, wherein an area of the second buffer circuit is smaller than an area of the first buffer circuit.

19. The signal sampling method of claim 13, wherein the first buffer circuit and the second buffer circuit are integrated into a buffer.

20. The signal sampling method of claim 19, wherein the buffer comprises:
a first transistor configured to operate as a current source according to a reference voltage and a supply voltage;
a second transistor configured to generate the second buffer signal according to the input signal; and
a third transistor coupled between the first transistor and the second transistor, and configured to generate the first buffer signal according to the input signal.
